(19) United States
(12) Patent Application Publication
(10) Pub. No.: US 2015/0000884 A1
(43) Pub. Date: Jan. 1, 2015

(54) PROTECTIVE COVER FOR PORTABLE ELETRONIC DEVICE

(71) Applicant: FIH (Hong Kong) Limited, Kowloon (HK)

(72) Inventors: JHIH-JIE JIANG, New Taipei (TW); KUANG-HSIA SHIH, New Taipei (TW); HAI-MING YANG, New Taipei (TW); HSUAN-HU CHANG, New Taipei (TW)

(73) Assignee: FIH (HONG KONG) LIMITED, Kowloon (HK)

(21) Appl. No.: 14/050,924

(22) Filed: Oct. 10, 2013

(30) Foreign Application Priority Data
Jun. 28, 2013 (TW) 102212273

(51) Int. Cl. H05K 5/03

(52) U.S. Cl. CPC H05K 5/03
USPC 165/185

(57) ABSTRACT

A protective cover for a portable electronic device includes a substrate and a heat dissipation unit assembled to the second surface. The substrate includes a metal part and a plastic part combined with the metal part. The metal part includes a first surface and an opposite second surface. The plastic part defines a receiving space for receiving the portable electronic device. When the portable electronic device is received in the receiving space, the heat dissipation unit contacts with the portable electronic device and transmits heat of the portable electronic device to the metal part so that the heat is dissipated by the metal part.

### BACKGROUND

1. Technical Field

The exemplary disclosure generally relates to protective covers, and particularly to a protective cover for a portable electronic device (e.g., mobile phones).

2. Description of Related Art

To prevent portable electronic devices such as a mobile phones from being damaged by shock, protective covers are used to protect the devices. However, protective covers can prevent heat dissipation of heat produced by components inside the devices.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 is a schematic view of an exemplary embodiment of a protective cover for a portable electronic device.

FIG. 2 is similar to the FIG. 1, but shown from another aspect.

FIG. 3 shows a cross-sectional view of the protective cover of FIG. 1 taken along line III-III.

### DETAILED DESCRIPTION

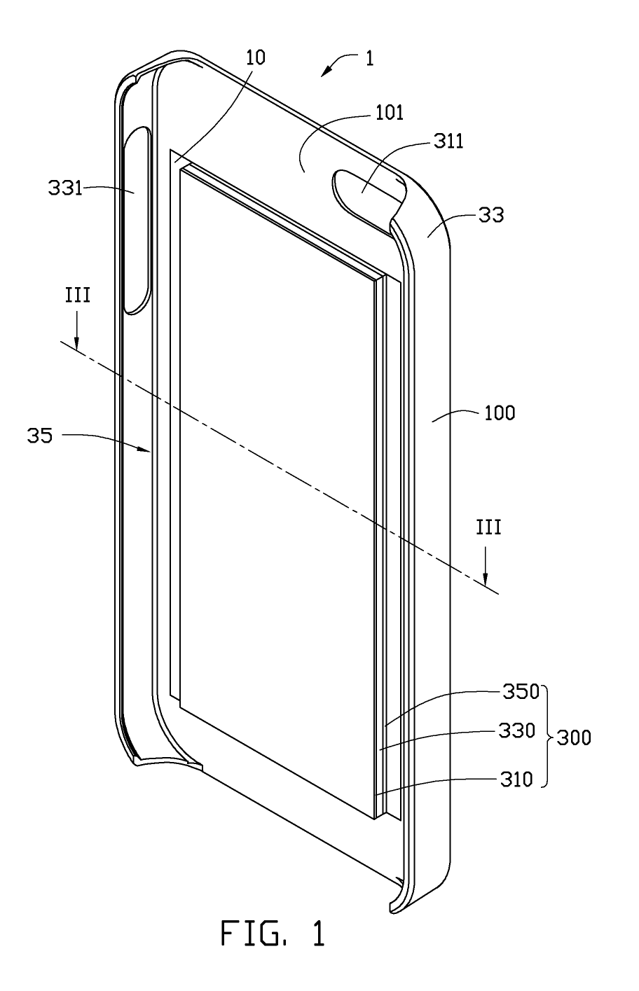

FIG. 1 is a schematic view of an exemplary embodiment of a protective cover 1 for a portable electronic device. The portable electronic device may be a mobile phone, an MP4 player, or a personal digital assistant (PDA).

The protective cover 1 includes a substrate 100 and a heat dissipation unit 300 fixed on an inner surface 101 of the substrate 100 by adhesive, welding, or injection molding.

The substrate 100 may be made of one of metal, plastic filled with thermally-conductive particles, and metal-plastic composite. The thermally-conductive particles include at least one material selected from a group consisting of aluminum oxide, aluminum hydroxide, boron nitride, aluminum nitride, silicon dioxide, zinc oxide, mica, graphite, aluminum, silver, or copper.

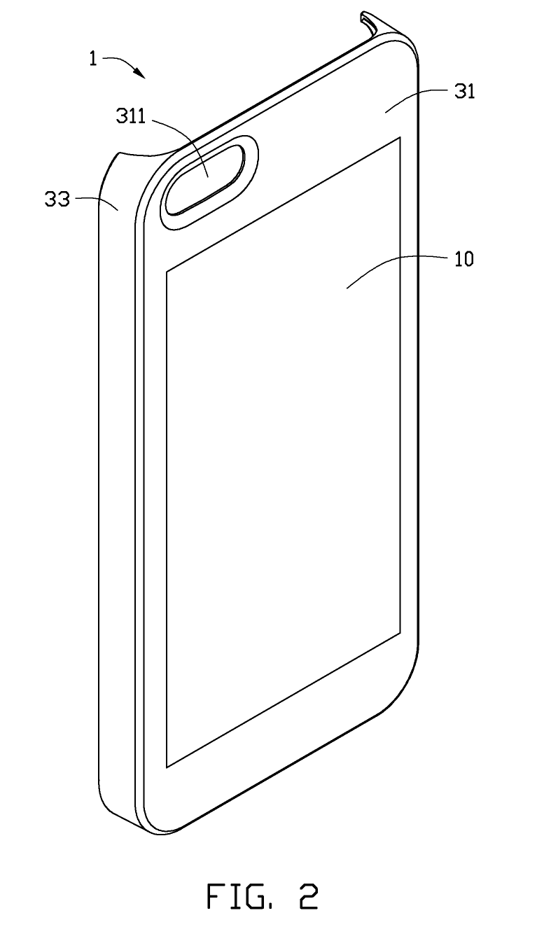

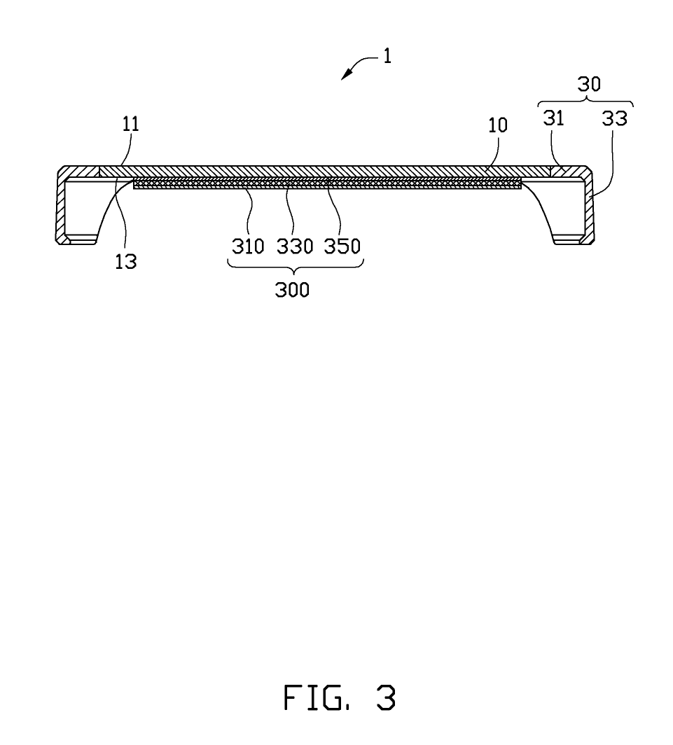

FIGS. 2 and 3 show that the substrate 100 includes a metal part 10 and a plastic part 30 combined with the metal part 10 by injection molding. The metal part 10 includes a first surface 11 and an opposite second surface 13 (best shown in FIG. 3). The second surface 13 is a portion of the inner surface 101. The heat dissipation unit 300 is attached to the second surface 13 by adhesive. The plastic part 30 includes a bottom plate 31 and two side plates 33 protruding from two opposite sides of the bottom plate 31. The bottom plate 31 and the two side plates 33 corporately define a receiving space 35, for receiving and holding the portable electronic device. The metal part 10 may be made of one of aluminum, aluminum alloy, iron, copper, and magnesium alloy.

The heat dissipation unit 300 may be made of one of metal, graphite, plastic filled with thermally-conductive particles, and metal-plastic composite. The thermally-conductive particles include at least one material selected from a group consisting of aluminum oxide, aluminum hydroxide, boron nitride, aluminum nitride, silicon dioxide, zinc oxide, mica, graphite, aluminum, silver, or copper, for example.

In this embodiment, the heat dissipation unit 300 includes a protective layer 310, a heat dissipation layer 330, and a combination layer 350 orderly combined together. The combination layer 350 is directly combined with the inner surface 101. In this embodiment, the combination layer 350 is formed on the second surface 13. When the portable electronic device is received in the receiving space 35, the protective layer 310 resists against the portable electronic device and the heat dissipation unit 300 is compressed and elastically deformed.

The protective layer 310 is made of plastic, such as polyethylene terephthalate, thermoplastic polyurethane, polycarbonate resin, or polyimide, which is capable of being mechanically deformed during compression. The protective layer 310 has a thickness of about 15 micrometers (μm) to about 30 μm. In an embodiment, the protective layer 310 has a thickness of about 20 μm. The protective layer 310 prevents the portable electronic device from being scratched by the heat dissipating layer 330.

The heat dissipating layer 330 is made of one of graphite, copper, aluminum, and plastic filled with thermally-conductive particles. The heat dissipating layer 330 has a thickness of about 80 μm to about 150 μm. In an embodiment, the heat dissipating layer 330 has a thickness of about 100 μm.

The combination layer 350 is made of plastic, such as acrylic resin, which is capable of being mechanically deformed during compression. The combination layer 350 enhances the combination between the heat dissipation unit 300 and the metal part 10.

In use, the portable electronic device is received in the first receiving space 35 so that the protective cover 1 covers the outside of the portable electronic device with the protective layer 310 contacting with the portable electronic device. Heat of the portable electronic device can be transmitted to the metal part 10 via the protective layer 310, the heat dissipating layer 330, and the combination layer 350 to be dissipated. Therefore, the portable electronic device protected by the protective cover 1 also can have adequate heat dissipation efficiency.

Furthermore, a distance between the portable electronic device received in the protective cover 1 and the second surface 13 can be smaller than a thickness of the heat dissipation unit 300 so that the protective layer 310 and the combination layer 350 is compressed by the portable electronic device and deformed and the protective layer 310 resists against the portable electronic device. Therefore, the portable electronic device can be stably held in the protective cover 1 and heat dissipation can be more effective.

In other embodiments, the heat dissipation unit 300 may be made of plastic which almost has no mechanically deformation during compression. A distance between the portable electronic device received in the protective cover 1 and the second surface 13 is equal to the thickness of the heat dissipation unit 300.

In addition, in a practical manufacturing process, to obtain a better heat dissipation effect, the heat dissipation unit 300 can be attached on the metal part 10 corresponding to main heating elements such as central processing units.

FIG. 1 shows that for the convenience of use, the protective cover 1 defines a first opening 311 in the bottom plate 31 and defines a second opening 331 in the side plate 33, to correspondingly expose a camera, a function key, and a connecting interface of the portable electronic device from the protective cover 1.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A protective cover for a portable electronic device, the protective cover comprising:
a substrate, the substrate comprising a metal part and a plastic part combined with the metal part, the metal part comprising a first surface and an opposite second surface, the plastic part defining a receiving space for receiving the portable electronic device;
and a heat dissipation unit assembled to the second surface, wherein when the portable electronic device is received in the receiving space, the heat dissipation unit contacts with the portable electronic device and transmits heat of the portable electronic device to the metal part so that the heat is dissipated by the metal part.

2. The protective cover of claim 1, wherein a distance between the portable electronic device received in the protective cover and the second surface is smaller than a thickness of the heat dissipation unit so that the heat dissipation unit resists against the portable electronic device.

3. The protective cover of claim 2, wherein the heat dissipation unit comprises a heat dissipation layer and a combination layer formed on the heat dissipation layer, the combination layer is combined with the second surface and deformed when the heat dissipation unit resists against the portable electronic device.

4. The protective cover of claim 3, wherein the heat dissipation unit further comprises a protective layer is formed on the dissipation layer, when the portable electronic device is received in the receiving space, the protective layer resists against the portable electronic device and deformed by the portable electronic device.

5. The protective cover of claim 3, wherein the heat dissipation layer is made of one of graphite, copper, aluminum, and plastic filled with thermally-conductive particles.

6. The protective cover of claim 3, wherein the combination layer is made of plastic, which is capable of being mechanically deformed during compression.

7. The protective cover of claim 4, wherein the protective layer is made of plastic, which is capable of being mechanically deformed during compression.

8. A protective cover for a portable electronic device, comprising:
a substrate, the substrate defining a receiving space for receiving the portable electronic device; and
a heat dissipation unit assembled to the substrate, wherein when the portable electronic device is received in the receiving space, the heat dissipation unit is positioned between the substrate and the portable electronic device and transmits heat of the portable electronic device to the substrate to dissipate the heat.

9. The protective cover of claim 8, wherein the substrate comprises a metal part and a plastic part combined with the metal part, the plastic part defines the receiving space, the heat dissipation unit is assembled to the metal part, and the metal part dissipates the heat.

10. The protective cover of claim 8, wherein a distance between the portable electronic device received in the protective cover and the metal part is smaller than a thickness of the heat dissipation unit so that the heat dissipation unit resists against the portable electronic device.

11. The protective cover of claim 10, wherein the heat dissipation unit comprises a heat dissipation layer and a combination layer formed on the heat dissipation layer, the combination layer is combined with the second surface and deformed when the heat dissipation unit resists against the portable electronic device.

12. The protective cover of claim 11, wherein the heat dissipation unit further comprises a protective layer is formed on the dissipation layer, when the portable electronic device is received in the receiving space, the protective layer resists against the portable electronic device and deformed by the portable electronic device.

13. The protective cover of claim 10, wherein the heat dissipation layer is made of one of graphite, copper, aluminum, and plastic filled with thermally-conductive particles.

14. The protective cover of claim 10, wherein the combination layer is made of plastic, which is capable of being mechanically deformed during compression.

15. The protective cover of claim 14, wherein the protective layer is made of plastic, which is capable of being mechanically deformed during compression.
